(19) United States
(12) Patent Application Publication
(10) Pub. No.: US 2009/0085187 A1
(43) Pub. Date: Apr. 2, 2009

(54) LOADING MECHANISM FOR BARE DIE PACKAGES AND LGA SOCKET

(76) Inventors: Ward Scott, Chandler, AZ (US); Luke Garner, Chandler, AZ (US); Ioan Sauciuc, Phoenix, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/864,819

(22) Filed: Sep. 28, 2007

(51) Int. Cl. H01L 23/48; H01R 12/00; H01L 21/00

(52) U.S. Cl. 257/690; 439/66; 438/122; 257/E21.001; 257/E23.01

(57) ABSTRACT

Methods and associated apparatus of reducing stress in a package Those methods may comprise providing a package comprising a die coupled to a substrate, wherein the substrate is disposed on an LGA socket, and wherein a TIM is disposed on a top surface of the die, and then attaching a thermal solution to the TIM, wherein at least one standoff is attached between the thermal solution and the substrate.

### BACKGROUND OF THE INVENTION

Microelectronic devices, such as central processing units (CPU), are typically assembled into packages that are then mounted onto a socket, such as a land grid array (LGA) socket, for attachment to a motherboard within a computer system. LGA sockets may utilize a loading mechanism to mate the package with the socket.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1c represent structures according to embodiments of the present invention.

FIG. 2 represent flow charts according to embodiments of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated apparatus for providing a loading mechanism for an LGA socket in microelectronic package applications are described. Those methods may comprise providing a package comprising a die coupled to a substrate, wherein the substrate is disposed on an LGA socket, and wherein a TIM is disposed on a top surface of the die, and then attaching a thermal solution to the TIM, wherein at least one standoff is attached between the thermal solution and the substrate. The methods and apparatus of the present invention provide a low Z-height for an LGA socket to be used in mobile applications, for example, as well as enabling the loading of a bare die to an organic package.

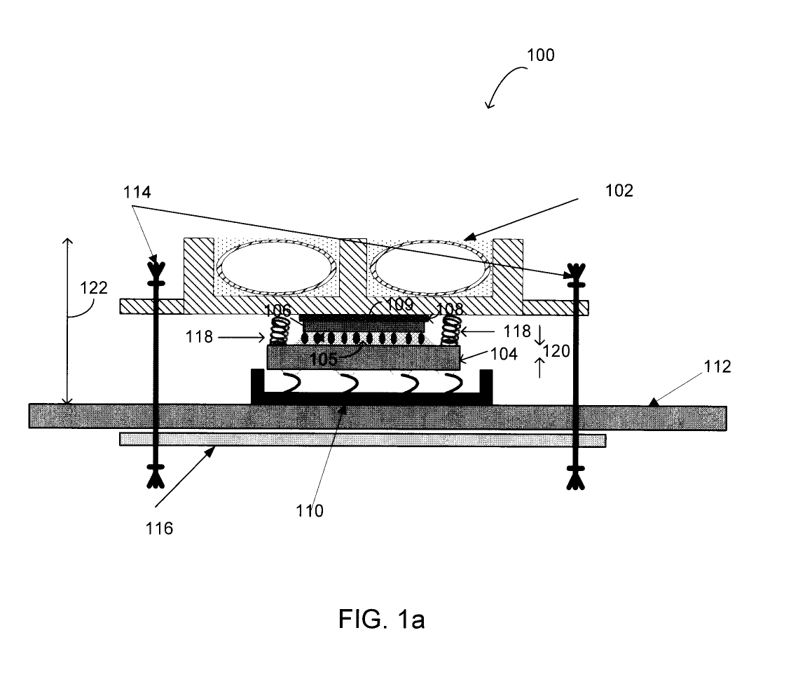

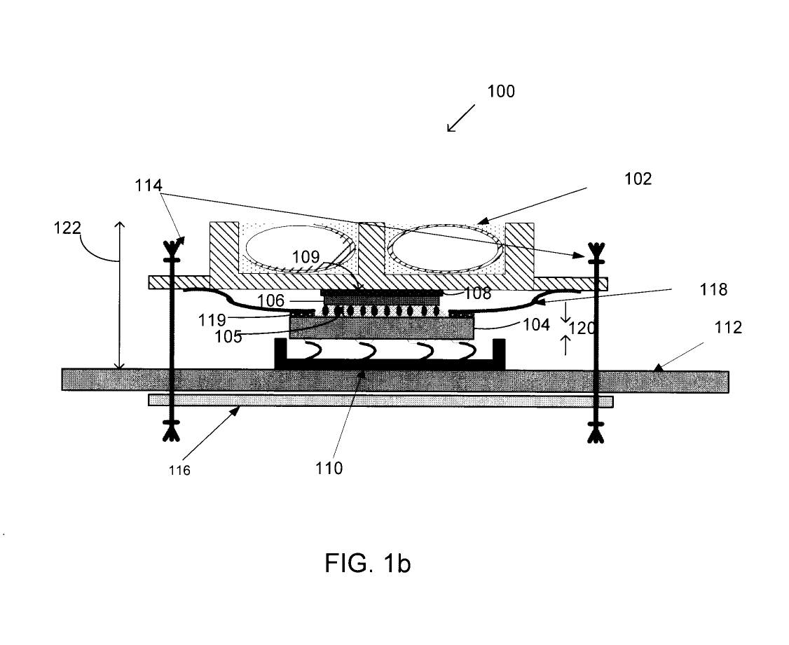

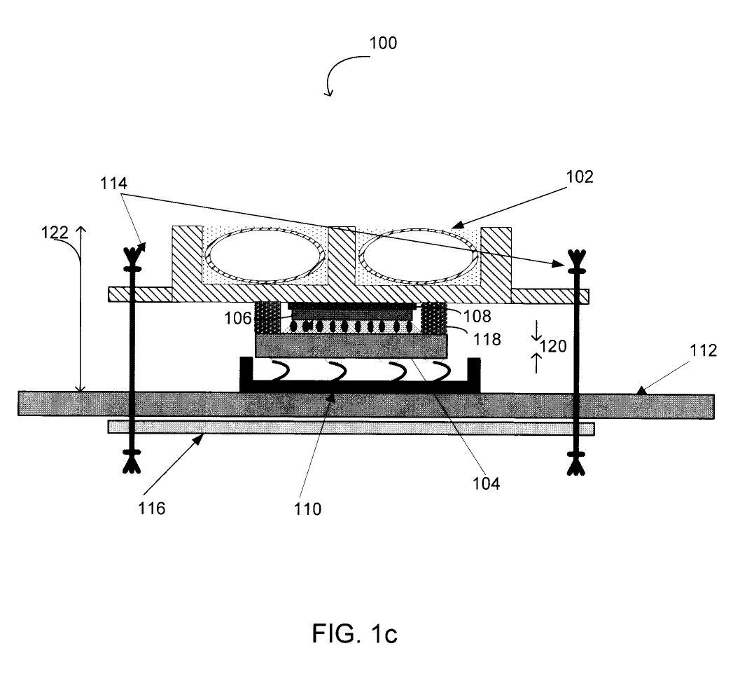

FIG. 1a illustrates an embodiment of a method and associated structures of providing loading mechanisms for an LGA socket in microelectronic package applications. FIG. 1a illustrates a package structure 100 that may comprise a thermal solution 102. In one embodiment, the thermal solution 102 may comprise at least one of a heat pipe, a heat spreader, a heat sink and a vapor chamber. The package structure 100 may further comprise a substrate 104 that may comprise a plurality of interconnect structures 105 that may connect a die 106 to the substrate 104. The substrate 104 may comprise a package substrate in some embodiments.

The package structure 100 may further comprise a thermal interface material (TIM) 108 that may be disposed between the thermal solution 102 and the die 106, and an LGA socket 110 that may connect the substrate 104 to a board 112. In one embodiment, the TIM 108 may be disposed on a top surface 109 of the die 106. A backing plate 116 may be disposed on a backside of the board 112 in some embodiments.

At least one mounting screw 114 may be disposed through the thermal solution 102 and through the board 112, and optionally through the backing plate 116. At least one standoff 118 may be attached to/between the thermal solution 102 and the substrate 104 to provide substrate loading. The at least one standoff 118 may comprise at least one of a helical spring, a spring plate, and a rubber frame, in some embodiments. When the at least one standoff 118 comprises a spring (as depicted in FIG. 1a), the spring may comprise a variety of geometries/designs depending upon the application, such as but not limited to a helical spring, for example. The thermal solution 102 may act simultaneously as a mechanism for the attachment of the LGA socket 110 and for the TIM 108 attachment.

The at least one standoff 118 may push against the package substrate 104. The mounting screw 114 may provide/adjust the load on the TIM 108 and the substrate 104, and the LGA socket 110. A spring compression 120 may be applied to the LGA socket 110 and the TIM 108 that is due to the force applied to the at least one mounting screw 114. In one embodiment, the at least one mounting screw 114 may sandwich the thermal solution 102 towards the backing plate 116 and/or board 112. In one embodiment, the at least one mounting screw 114 that is disposed between the thermal solution 102 and the board 112 may adjust the load on the at least one standoff 118. In one embodiment, the load on the LGA socket 110 and the TIM 108 may be optimized to the particular desired load specifications by adjusting the load on the at least one standoff 118.

The at least one mounting screw 114 may provide a novel loading mechanism for the LGA socket 110 and may be used in bare die organic package applications, in some embodiments. The thermal solution 102 may act simultaneously as a mechanism for the attachment of the LGA socket 110 and for the TIM 108. The loading mechanism of the thermal solution 102 may provide load through the die 106 and package 104 and as a retention mechanism for the TIM 108.

In one embodiment, a Z height 122 of the package structure 100 may be below about 8 mm. A lower Z height 122 of the package structure 100 may enable the LGA socket 110 to be used in mobile applications that may benefit from a low Z height 122, as well as enabling the loading of a bare die organic package. In systems where the Z-height 122 is critical and limited, such as in mobile laptops, the load mechanism of the present invention can achieve a low form factor requirement through integrating the load mechanism with the existing thermal load mechanism for the heatsink, for example, thus providing a load distribution through the microelectronic device and the package body.

FIG. 1b illustrates another embodiment of the present invention. The package structure 100 may comprise at least one standoff 118, wherein the at least one standoff 118 may comprise a spring plate. In one embodiment, the spring plate may be disposed on a washer 119 that may be disposed on the substrate 104. The washer 119 may comprise a rubber washer in one embodiment, but in general may comprise any material suitable for the particular application. In one embodiment, the thermal solution 102 may act simultaneously as a mechanism for the attachment of the LGA socket 110 and for the TIM 108 attachment.

The spring plate 118 may push against the package substrate 104. The spring plate (which may comprise a variety of geometries/designs depending upon the application) may push against the package substrate 104. In one embodiment, the washer 119 may serve to protect the package substrate 104. A spring compression 120 may be applied to the LGA socket 110 and the TIM 108 that is due to the force applied to the at least one mounting screw 114. The at least one mounting screw 114 may provide/adjust the load on the TIM 108 and the substrate 104, and the LGA socket 110. In one embodiment, the at least one mounting screw 114 that is disposed between the thermal solution 102 and the board 112 may adjust the load on the at least one spring plate 118. In one embodiment, the load on the LGA socket 110 and the TIM 108 may be optimized to the particular desired load specifications by adjusting the load on the at least one spring plate 118.

In one embodiment, the Z height 122 of the package structure 100 may be below about 8 mm. A lower Z height 122 of the package structure 100 may enable the LGA socket 110 to be used in mobile applications, as well as enabling the loading of a bare die organic package.

FIG. 1c illustrates another embodiment of the present invention. The package structure 100 may comprise at least one standoff 118, wherein the at least one standoff 118 may comprise a rubber frame 118, that may be used in a spring-like fashion. The thermal solution 102 may act simultaneously as a mechanism for the attachment of the LGA socket 110 and for the TIM 108 attachment.

The rubber frame 118 may push against the package substrate 104. The rubber frame (which may comprise a variety of geometries/designs depending upon the application) may push against the package substrate 104. A spring compression 120 may be applied to the LGA socket 110 and the TIM 108 that is due to the force applied to the at least one mounting screw 114. The at least one mounting screw 114 may provide/adjust the load on the TIM 108 and the substrate 104, and the LGA socket 110. In one embodiment, the at least one mounting screw 114 that is disposed between the thermal solution 102 and the board 112 may adjust the load on the at least one rubber frame 118. In one embodiment, the load on the LGA socket 110 and the TIM 108 may be optimized to the particular desired load specifications by adjusting the load on the at least one rubber frame 118.

In one embodiment, the Z height 122 of the package structure 100 may be below about 8 mm. A lower Z height 122 of the package structure 100 may enable the LGA socket 110 to be used in mobile applications, as well as enabling the loading of a bare die organic package.

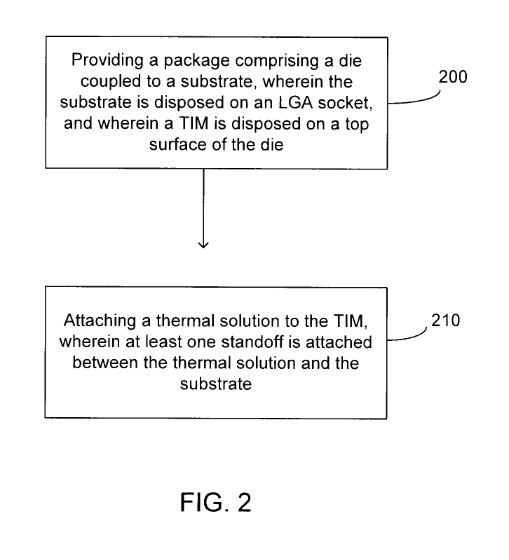

FIG. 2 depicts a flow chart according to an embodiment of the present invention. At step 200, a package is provided comprising a die coupled to a substrate, wherein the substrate is disposed on an LGA socket, and wherein a TIM is disposed on a top surface of the die. At step 210, a thermal solution is attached to the TIM, wherein at least one standoff is attached between the thermal solution and the substrate.

As described above, the present invention provides methods and associated structures for the enablement of low Z height mobile packages incorporating LGA sockets. A lower Z-height may be advantageous for the attachment of the LGA socket through the integration of an enabled thermal solution into the LGA load mechanism. The loading mechanisms of the various embodiments of the present invention provides for loading through the die and the package, such as an organic package, to complete electrical continuity with the LGA socket.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that a package, such as may be found in a printed circuit board, is well known in the art. Therefore, it is appreciated that the Figures provided herein illustrate only portions of an exemplary package assembly that pertains to the practice of the present invention. Thus the present invention is not limited to the structures described herein.

1. A method comprising:
providing a package comprising a bare die coupled to a substrate, wherein the substrate is disposed on an LGA socket, and wherein a TIM is disposed directly on a top surface of the bare die; and
attaching a thermal solution to the TIM, wherein at least one standoff is attached between the thermal solution and the substrate.

2. The method of claim 1 further comprising wherein the LGA socket is disposed on a board.

3. The method of claim 2 further comprising wherein at least one mounting screw disposed between the thermal solution and The board adjust the load on the at least one spring.

4. The method of claim 3 wherein adjusting the load on the at least one mounting screw adjusts the load on the LGA socket and the TIM.

5. The method of claim 1 wherein the thermal solution provides a loading mechanism for the LGA socket by providing a load through the die and the substrate to the LGA socket.

6. The method of claim 1 wherein the thermal solution provides a loading mechanism for the package.

7. The method of claim 1 further comprising wherein a Z height of the package is below about 8 mm.

8. The method of claim 1 further comprising wherein the package comprises a bare die organic package.

9. The method of claim 1 further comprising wherein the at least one standoff comprises at least one of a spring, a spring plate, and a rubber frame.

10. The method of claim 1 further comprising wherein the thermal solution comprises at least one of a heat pipe, a heat spreader, a heat sink and a vapor chamber.

11. A method comprising:
providing a mobile package comprising a bare die coupled to an organic substrate, wherein the organic substrate is disposed on an LGA
socket and wherein a TIM is disposed directly on a top surface of the bare die; and
attaching a thermal solution to the TIM, wherein at least one standoff is attached between the thermal solution and the organic substrate, and wherein the thermal solution provides a loading mechanism for the LGA socket by providing a load through the die and the organic substrate to the LGA socket.

12. The method of claim 11 further comprising wherein the at least one standoff comprises at least one of a spring, a spring plate, and a rubber frame.

13. The method of claim 11 further comprising wherein a Z height of the mobile package is below about 8 mm.

14. A structure comprising:
a package comprising a bare die coupled to a substrate, wherein the substrate is disposed on an LGA socket, and wherein a TIM is disposed directly on a top surface of the bare die; and
a thermal solution disposed on the TIM, wherein at least one standoff is attached between the thermal solution and the substrate.

15. The structure of claim 14 further comprising wherein at least one mounting screw is disposed between the thermal solution and the board that is capable of adjusting the load on the LGA socket.

16. The structure of claim 14 further comprising wherein a Z height of the package is below about 8 mm and wherein the package comprises a mobile package.

17. The structure of claim 14 further comprising wherein the package comprises a bare die organic package.

18. The structure of claim 14 further comprising wherein the at least one standoff comprises at least one of a spring, a spring plate, and a rubber frame.

19. The structure of claim 1 further comprising wherein the thermal solution comprises at least one of a heat pipe, a heat spreader, a heat sink and a vapor chamber

20. The structure of claim 18 wherein a washer is disposed between the spring plate and the substrate.
